(19) United States
(12) Patent Application Publication
(10) Pub. No.: US 2012/0202340 A1
(43) Pub. Date: Aug. 9, 2012

(54) N-TYPE DOPING OF ZINC TELLURIDE

(75) Inventors: Xianfeng LU, Beverly, MA (US); Ludovic GODET, Boston, MA (US); Anthony RENAU, West Newbury, MA (US)

(73) Assignee: VARIAN SEMICONDUCTOR EQUIPMENT ASSOCIATES, INC., Gloucester, MA (US)

(21) Appl. No.: 13/021,064

(22) Filed: Feb. 4, 2011

(51) Int. Cl. H01L 21/425

(52) U.S. Cl. 438/515; 438/519; 257/E21.473

(57) ABSTRACT

ZnTe is implanted with a first species selected from Group III and a second species selected from Group VII. This may be performed using sequential implants, implants of the first species and second species that are at least partially simultaneous, or a molecular species comprising an atom selected from Group III and an atom selected from Group VII. The implants may be performed at an elevated temperature in one instance between 70° C. and 800° C.

### FIELD

This invention relates to doping zinc telluride (ZnTe) and, more particularly, to n-type doping of ZnTe.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the lattice of the workpiece material to form an implanted region.

Workpieces or films on workpieces may be composed of many different materials. For example, ZnTe is a wide band gap semiconductor material with a direct band gap of around 225 eV. ZnTe may be used in ultra-high efficiency solar cells, pure green light emitting diodes (LEDs), laser diodes, optoelectronic detectors, compound semiconductors, and other applications known to those skilled in the art. However, it is difficult to perform n-type doping of ZnTe or ZnTe workpieces. In-situ doping during ZnTe growth has been performed, such as using molecular beam epitaxy (MBE) or metalorganic chemical vapor deposition (MOCVD). Doping during ZnTe growth cannot control the Zn vacancy concentration, which is one mechanism that prevents n-type doping of ZnTe. This is at least partly because in-situ doping during ZnTe growth involves competition between dopants and Zn atoms. This competition results in Zn vacancies. Zn vacancies is a p-type characteristic and will compensate for n-type doping of ZnTe. What is needed is a new method of doping ZnTe and, more particularly, n-type doping of ZnTe.

### SUMMARY

According to a first aspect of the invention, a method of doping is provided. The method comprises implanting a ZnTe layer with a first species selected from Group III. The ZnTe layer also is implanted with a second species selected from Group VII.

According to a second aspect of the invention, a method of doping is provided. The method comprises implanting a ZnTe layer with a first species selected from Group III and a second species selected from Group VII. The ZnTe layer is at a temperature between 70° C. and 800° C. during the implantation of the first species and second species.

According to a third aspect of the invention, a method of doping is provided. The method comprises implanting a ZnTe layer with a molecular species comprising an atom selected from Group III and an atom selected from Group VII.

### BRIEF DESCRIPTION OF THE DRAWINGS

For a better understanding of the present disclosure, reference is made to the accompanying drawings, which are incorporated herein by reference and in which:

FIG. 1 is a view of one embodiment of a ZnTe crystal structure;

FIG. 2 is a cross-sectional view of implanting a workpiece with a first species;

FIG. 3 is a cross-sectional view of implanting a workpiece with a second species;

FIG. 4 is a view of one embodiment of a doped ZnTe crystal structure;

FIG. 5 is a cross-sectional view of implanting a workpiece with a molecule;

FIG. 6 is a chart comparing implantation introduced Zn vacancies to depth; and

FIG. 7 is a simplified block diagram of a beam-line ion implanter;

### DETAILED DESCRIPTION

These methods are described herein in connection with an ion implanter. However, while a beam-line ion implanter is specifically described, other systems and processes involved in semiconductor manufacturing or other systems that use plasma or generate ions also may be used. Some examples include a plasma doping tool, a plasma immersion tool, a flood implanter, an implanter that focuses a plasma or ion beam, or an implanter that modifies the plasma sheath. Thus, the invention is not limited to the specific embodiments described below.

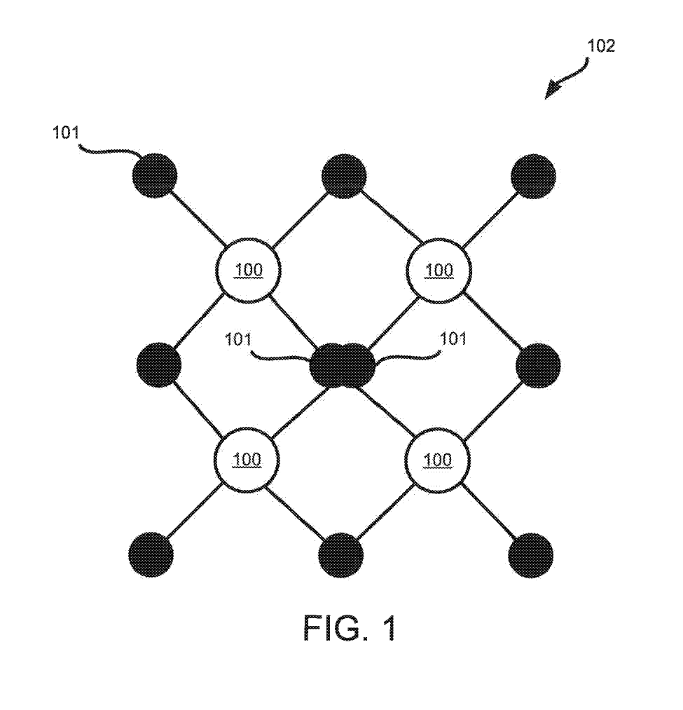

FIG. 1 is a view of one embodiment of a ZnTe crystal structure 102. ZnTe may have a cubic crystal structure like a diamond. However, ZnTe may have other crystal structures such as hexagonal (wurzite), polycrystalline, or amorphous. The ZnTe crystal structure 102 illustrated in FIG. 1 includes Zn atoms 100 and Te atoms 101 (illustrated as black in FIG. 1). The illustration in FIG. 1 is a two-dimensional approximation of a three-dimensional structure. Thus, some atoms in the crystal structure would go into or out of the page.

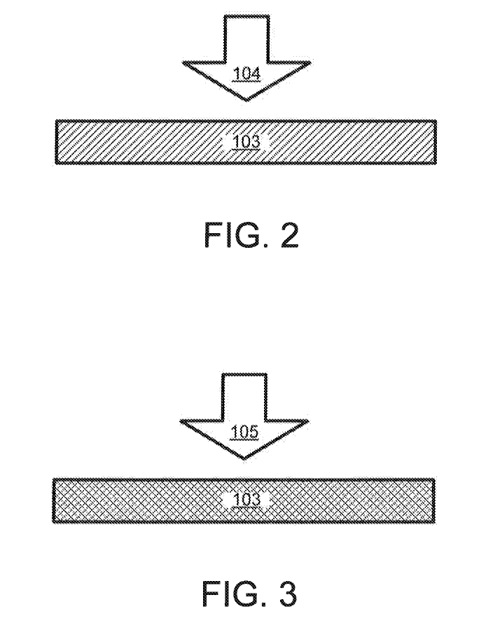

FIG. 2 is a cross-sectional view of implanting a workpiece with a first species. A workpiece 103, which is ZnTe or has a ZnTe film on at least one surface, is grown. Thus, the workpiece 103 may be or may contain a ZnTe layer. So while the term “workpiece” is used herein, a ZnTe layer also may be processed using the embodiments disclosed herein. MBE, for example, may be used to grow the workpiece 103, though other methods are possible.

The workpiece 103 is implanted with a first species 104. This first species 104 is selected from Group III. Examples of the first species 104 include B, Al, Ga, and In. Of course, other ions may be implanted as the first species 104. The first species 104 implants the entirety of the workpiece 103, though implants to particular depths or to particular regions also are possible.

FIG. 3 is a cross-sectional view of implanting a workpiece with a second species. The workpiece 103 is then implanted with a second species 105. This second species 105 is selected from Group VII. Examples of the second species 105 include F, Cl, Br, and I. Of course, other ions may be implanted as the second species 105. The second species 105 implants the entirety of the workpiece 103, though implants to particular depths or to depths different than that of the first species 104 are possible.

While the second species 105 is shown being implanted after the first species 104, the implantation may be performed in either order. In another particular embodiment, the first species 104 and second species 105 are implanted simultaneously or at least partially simultaneously. In one example, a cocktail or plasma containing both the first species 104 and second species 105 is formed and implanted into the workpiece 103 at the same time. In yet another particular embodiment, the first species 104 and second species 105 are implanted sequentially without breaking vacuum around the workpiece 103.

In a first instance, the first species 104 is Ga and the second species 105 is I. In a second instance, the first species 104 is Al and the second species 105 is Cl. The combinations can enhance a doping effect because Ga or Al will replace Zn atoms in ZnTe and I or Cl will replace Te atoms. Other combinations of first species 104 and second species 105 are possible. These are merely examples. The first species 104 and second species 105 may be generated from atomic or molecular feed gases in one embodiment.

In one particular embodiment, the implantation of the first species 104 or second species 105 may be followed by an anneal. For example, a laser or flash anneal may be performed. This anneal recrystallizes the workpiece 103. Laser annealing, for example, may activate the first species 104 and second species 105 without producing additional Zn vacancies. The time duration of the anneal may be configured to reduce the number of Zn vacancies produced. Annealing using a laser anneal or flash anneal may minimize the competition process between the implanted species and Zn vacancies, which may reduce the Zn vacancy concentration. In an alternate embodiment, rapid thermal anneal (RTA) or other annealing methods may be used.

In another embodiment, the implantation of the first species 104 or second species 105 may be performed at an elevated temperature. In one instance, the workpiece 103 is pre-heated prior to the implantation steps to above room temperature. In another instance, the workpiece 103 is heated during the implantation steps. For example, the workpiece 103 may be pre-heated or heated to between approximately 70° C. and 800° C. In one particular embodiment, the workpiece 103 heated to between approximately 300° C. and 800° C. during implantation. Implantation at an elevated temperature may reduce damage to the crystal lattice of the workpiece 103 or may repair or anneal damage to the crystal lattice of the workpiece 103. Reduced damage may enable particular annealing methods that are less effective with more damage to the crystal lattice. The temperature of the workpiece 103 is configured to reduce or prevent diffusion of the species implanted into the workpiece 103. Furthermore, the temperature of the workpiece 103 is configured to reduce or prevent amorphization of the workpiece 103 due to implant. Partial amorphization may occur in one instance if this partial amorphization can be removed using, for example, a laser anneal or flash anneal. In one particular embodiment, the workpiece 103 is heated during implantation to a varying temperature. This temperature may be ramped or otherwise adjusted during the implantation or between the implantation of the first species 104 and second species 105.

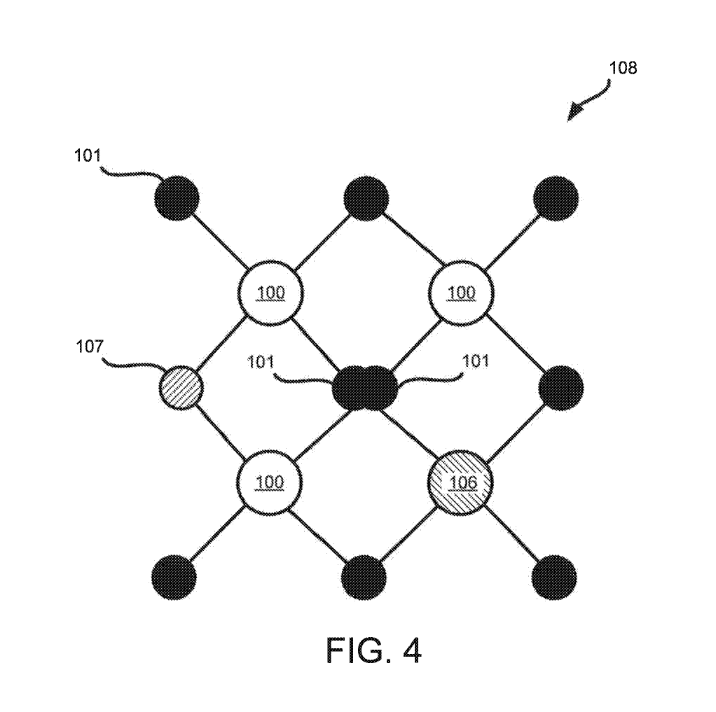

FIG. 4 is a view of one embodiment of a doped ZnTe crystal structure. The implanted ZnTe crystal structure 108 includes Zn atoms 100, Te atoms 101, first species atoms 106, and second species atoms 107. The first species atoms 106 are selected to have a size similar to the Zn atoms 100 in one instance. The second species atoms 107 are selected to have a size similar to the Te atoms 101 in a second instance. Similar-sized atoms may reduce stress or strain within the implanted ZnTe crystal structure 108. Dose and energy during implantation of the first species atoms 106 and second species atoms 107 are configured to obtain the desired dopant incorporation in the implanted ZnTe crystal structure 108.

Implanting smaller ions than the examples listed herein into the implanted ZnTe crystal structure 108 may induce strain in the crystal lattice. This is because the Zn atoms 100, atomic weight 65.39, and Te atoms 127.60, are fairly large compared to smaller n-type dopants. Implantation of smaller ions to cause strain may be beneficial for certain applications.

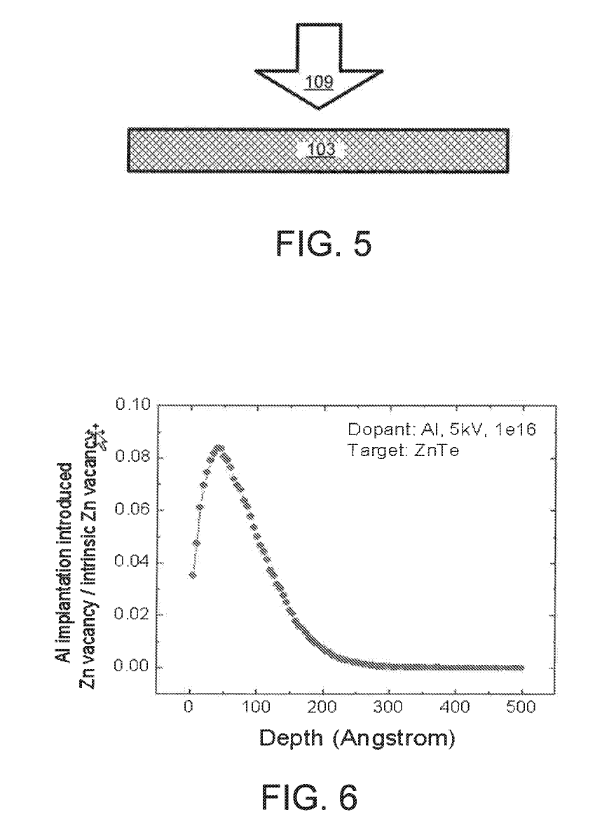

FIG. 5 is a cross-sectional view of implanting a workpiece with a molecule. The workpiece 103 is implanted with a molecular species 109. This molecular species 109 contains both an atom from Group III and an atom from Group VII. For example, the molecular species 109 may be BF₃ ions. The molecular species 109 also may contain a combination of B, Ga, or Al and F, Cl, or I. Of course, other examples of the molecular species 109 are possible.

The embodiments disclosed herein may introduce fewer Zn vacancies than in-situ doping, such as that performed by MBE or MOCVD, because there is less competition between dopants and the Zn than by in-situ doping during ZnTe growth. FIG. 6 is a chart comparing implantation introduced Zn vacancies to depth. The Zn vacancies in FIG. 6 are caused by Al implantation at 5 kV and 1E16 cm⁻². In one particular example, 8.4% Zn vacancies were formed. This is approximately ten times less than that caused by MBE or MOCVD in-situ doping.

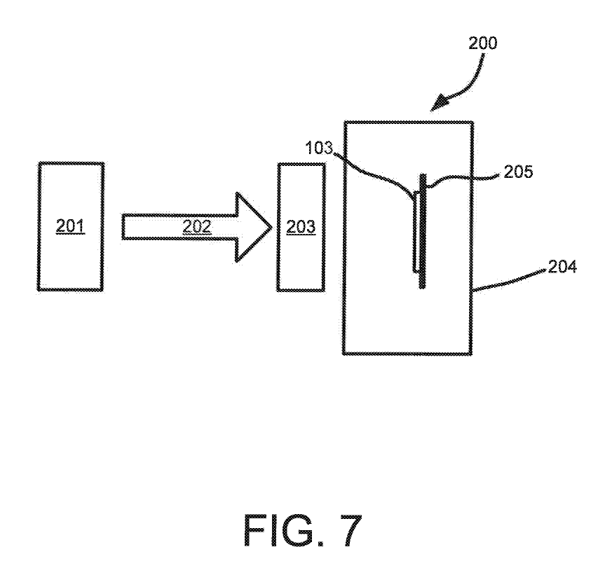

FIG. 7 is a simplified block diagram of a beam-line ion implanter. Those skilled in the art will recognize that the beam-line ion implanter 200 is only one of many examples of differing beam-line ion implanters. In general, the beam-line ion implanter 200 includes an ion source 201 to generate ions that are extracted to form an ion beam 202, which may be, for example, a ribbon beam or a spot beam. The ion beam 202 of FIG. 7 may correspond to the first species 104, the second species 105, or the molecular species 109 of FIG. 2, 3, or 5.

The ion beam 202 may be mass analyzed and converted from a diverging ion beam to a ribbon ion beam with substantially parallel ion trajectories in one instance. The ion beam 202 also may not be mass analyzed prior to implantation. The beam-line ion implanter 200 may further include an acceleration or deceleration unit 203 in some embodiments.

An end station 204 supports one or more workpieces, such as the workpiece 103, in the path of the ion beam 202 such that ions of the desired species are implanted into workpiece 103. The end station 204 may include workpiece holder, such as platen 205, to support the workpiece 103. The workpiece holder also may be other mechanisms such as a conveyor belt. This particular end station 204 also may include a scanner (not illustrated) for moving the workpiece 103 perpendicular to the long dimension of the ion beam 202 cross-section, thereby distributing ions over the entire surface of workpiece 103.

The beam-line ion implanter 200 may include additional components known to those skilled in the art such as automated workpiece handling equipment, Faraday sensors, or an electron flood gun. It will be understood to those skilled in the art that the entire path traversed by the ion beam is evacuated during ion implantation. The beam-line ion implanter 200 may incorporate hot or cold implantation of ions in some embodiments. Hot implantation may use lamps, LEDs, a platen 205 or other workpiece holder that is heated, or other mechanisms known to those skilled in the art. Pre-heating the workpiece 103 may be performed on the workpiece holder, a separate area of the end station 204, or in a separate chamber of the beam-line ion implanter 200.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of doping comprising:
implanting a ZnTe layer with a first species selected from Group III; and
implanting said ZnTe layer with a second species selected from Group VII wherein said ZnTe layer is at a temperature between 450° C. and 800° C. during said implanting said first species and said implanting said second species.

2. The method of claim 1, wherein said first species is selected from the group consisting of B, Al, Ga, and In and said second species is selected from the group consisting of F, Cl, Br, and I.

3. The method of claim 1, wherein said first species is Ga and said second species is I.

4. The method of claim 1, wherein said first species is Al and said second species is Cl.

5. The method of claim 1, wherein said implanting said first species and said implanting said second species occurs at least partially simultaneously.

6. The method of claim 5, wherein said implanting said first species and said implanting said second species comprises implanting BF₃ molecular ions.

7. (canceled)

8. The method of claim 1, further comprising annealing said ZnTe layer after said implanting said first species and said implanting said second species.

9. The method of claim 1, further comprising heating said ZnTe layer above room temperature prior to said implanting said first species and said implanting said second species.

10. A method of doping comprising:
implanting a ZnTe layer with a first species selected from Group III, wherein said ZnTe layer is at a first temperature between 450° C. and 800° C. during said implanting said first species; and
implanting said ZnTe layer with a second species selected from Group VII, wherein said ZnTe layer is at a second temperature between 450° C. and 800° C. during said implanting said second species.

11. The method of claim 10, wherein said first species is selected from the group consisting of B, Al, Ga, and In and said second species is selected from the group consisting of F, Cl, Br, and I.

12. The method of claim 10, wherein said implanting said first species and said implanting said second species occurs at least partially simultaneously.

13. The method of claim 12, wherein said implanting said first species and said implanting said second species comprises implanting BF₃ molecular ions.

14. The method of claim 10, further comprising annealing said ZnTe layer after said implanting said first species and said implanting said second species.

15. The method of claim 10, further comprising heating said ZnTe layer above room temperature prior to said implanting said first species and said implanting said second species.

16. A method of doping comprising:
implanting a ZnTe layer with molecular species comprising an atom selected from Group III and an atom selected from Group VII, wherein said ZnTe layer is at a temperature between 450° C. and 800° C. during said implanting said molecular species.

17. The method of claim 16, wherein said atom selected from Group III is B, Ga, or Al and said atom selected from Group VII is F, Cl, or I.

18. (canceled)

19. The method of claim 16, further comprising annealing said ZnTe layer after said implanting.

20. The method of claim 16, further comprising heating said ZnTe layer above room temperature prior to said implanting.
